(19) United States
(12) Patent Application Publication
(10) Pub. No.: US 2025/0230298 A1
(43) Pub. Date: Jul. 17, 2025

(54) COMPOSITION, FLUORORESIN SHEET, AND METHOD FOR PRODUCING SAME

(71) Applicant: DAIKIN INDUSTRIES, LTD., Osaka (JP)

(72) Inventors: Yuki UEDA, Osaka (JP); Shingo OKUNO, Osaka (JP); Kyohei SAWAKI, Osaka (JP); Moe HOSOKAWA, Osaka (JP); Yoshito TANAKA, Osaka (JP); Akiyoshi YAMAUCHI, Osaka (JP); Yosuke KISHIKAWA, Osaka (JP)

(73) Assignee: DAIKIN INDUSTRIES, LTD., Osaka (JP)

(21) Appl. No.: 19/098,138

(22) Filed: Apr. 2, 2025

Related U.S. Application Data
(63) Continuation of application No. PCT/JP2023/036151, filed on Oct. 4, 2023.

(30) Foreign Application Priority Data
Oct. 7, 2022 (JP) 2022-162084
Mar. 8, 2023 (JP) 2023-035263
Aug. 28, 2023 (JP) 2023-137873

(51) Int. Cl. C08K 9/06; C08J 3/20; C08J 5/18; H05K 1/03

(52) U.S. Cl. CPC C08K 9/06; C08J 3/203; C08J 5/18; C08J 2327/18; C08K 2201/005; H05K 1/0373; H05K 2201/0209; H05K 2201/0355

(57) ABSTRACT

A composition for obtaining a fluororesin sheet having excellent performance in terms of a low dielectric constant, a low loss, and low thermal expansion, a fluororesin sheet, and a method for producing the same, are provided. The composition containing a fluororesin and a filler having a ratio of (a dielectric loss tangent of the filler measured at 10 GHz)/(a surface area of the filler (m²/g)) of 0.00001 to 0.00035.

### CROSS REFERENCE TO RELATED APPLICATIONS

This application is a Rule 53(b) Continuation of International Application No. PCT/JP2023/036151 filed Oct. 4, 2023, claiming priorities based on Japanese Patent Application No. 2022-162084 filed Oct. 7, 2022, Japanese Patent Application No. 2023-035263 filed Mar. 8, 2023, and Japanese Patent Application No. 2023-137873 filed Aug. 28, 2023, the respective disclosures of which are incorporated herein by reference in their entirety.

### TECHNICAL FIELD

The present disclosure relates to a composition, a fluororesin sheet, and a method for producing the same.

### BACKGROUND ART

In high-frequency printed wiring boards, those with a low transmission loss have been demanded. In such high-frequency printed wiring boards, fluororesin films are publicly known to be used (Patent Literature 1 and the like). Moreover, Patent Literatures 2 and 3 describe the use of fluororesins compounded with a filler as wiring board materials.

Furthermore, Patent Literature 4 discloses the use of a fluororesin composition in which a fluororesin has been compounded with spherical silica particles is used for a circuit board.

### CITATION LIST

### Patent Literature

Patent Literature 1: Japanese Patent Laid-Open No. 2015-8260

Patent Literature 2: Japanese Patent Laid-Open No. 63-259907

Patent Literature 3: Japanese Translation of PCT International Application Publication No. 2022-510017

Patent Literature 4: International Publication No. WO2020/145133

### SUMMARY

The present disclosure is a composition characterized in that it comprises a fluororesin and a filler having a ratio of (a dielectric loss tangent of the filler measured at 10 GHz)/(a surface area of the filler (m²/g)) of 0.00001 to 0.00035.

### DESCRIPTION OF EMBODIMENTS

The present disclosure will be described in detail below.

Considerable research has been conducted on compositions in which a filler is compounded with a fluororesin. In the field of high-frequency printed wiring boards, on the other hand, a high level of performance, such as a low dielectric constant, a low loss, and low expansion, is required in recent years. Investigation on achieving such a high level of a low dielectric constant, a low loss, and low expansion has not necessarily been sufficient.

An object of the present disclosure is to provide a composition for obtaining a fluororesin sheet with a high level of a low dielectric constant, a low loss, and low expansion, which has not been achieved before.

### Filler

The composition of the present disclosure is characterized in that it contains a fluororesin and a filler, wherein the filler has a ratio of (the dielectric loss tangent of the filler measured at 10 GHz)/(a surface area of the filler (m²/g)) of 0.00035 to 0.00001. Namely, the composition is characterized by the use of filler that satisfies the aforementioned specific parameters.

The dielectric loss tangent of the filler is greatly affected by a polar functional group on its surface. For example, in the case of silica, the amount of a Si—OH group on its surface affects the dielectric loss tangent. More specifically, the greater the amount of Si—OH groups on its surface is, the greater the dielectric loss tangent of the filler is. For this reason, in the present disclosure, it is preferable to reduce the amount of Si—OH on a surface.

From such a viewpoint, the ratio of (a dielectric loss tangent of the filler measured at 10 GHz)/(a surface area of the filler (m²/g)) is an index indicating the amount of surface polar functional groups per unit surface area of the filler. The present inventors have found that when the amount of such a surface polar functional group is reduced and the ratio falls within the aforementioned predetermined range, a fluororesin sheet with a particularly excellent low dielectric constant, a low loss, and low expansion can be obtained, and thus have completed the present disclosure.

In order to obtain a filler having a ratio of (the dielectric loss tangent of the filler measured at 10 GHz)/(a surface area of the filler (m²/g)) that falls within the aforementioned range, in addition to selecting a filler to be used, it is required to be surface treated. That is, the surface treatment allows a polar functional group present on a filler surface to be reacted and reduces the amount of polar functional groups, thereby making it possible to the ratio within the aforementioned range. Such surface treatment will be described in detail below.

The upper limit of the above-described (the dielectric loss tangent of the filler measured at 10 GHz)/(a surface area of the filler (m²/g)) is more preferably 0.00030 and still more preferably 0.00025.

In the present disclosure, the dielectric loss tangent of the filler measured at 10 GHz is measured using a cylindrical cavity resonator and a network analyzer, with a filler powder sample filled in a quartz tube and loaded into the resonator. The properties of the resonator (resonant frequency and Q value) are acquired before and after the sample is intercalated, and the dielectric loss tangent is calculated from the results. This measurement method complies with the Japanese Industrial Standards JIS 2565 Measuring methods for ferrite cores for microwave device, and measurements are made in an environment at room temperature of 25° C. and a humidity of 40%.

In the present disclosure, the dielectric loss tangent of the filler measured at 10 GHz is not limited, but is preferably 0.0015 or less. Such a value is preferable in terms of the fluororesin sheet, having a low loss. The upper limit thereof is more preferably 0.0025 and still more preferably 0.002.

In the present disclosure, the surface area (m²/g) of the filler is not limited, but is preferably 1 to 10. Within the above-described range of the surface area, the fluororesin sheet has a favorable balance between the low loss and low linear expansion, which is preferable in this respect. The lower limit thereof is more preferably 1.2 and still more preferably 1.5. The upper limit thereof is more preferably 9 and still more preferably 7.

In the present disclosure, the surface area (m²/g), which is the specific surface area, of the filler is a value obtained based on a BET method, and can be measured using a specific surface area measurement apparatus such as “Macsorb HM model-1208” (manufactured by Mountech Co. Ltd.). It is to be noted that when the fluororesin sheet of the present disclosure contains two or more types of fillers, the surface area measured for the entire fillers compounded falls within the aforementioned range.

The filler in the present disclosure preferably has an average particle size of 0.5 to 250 μm. Incidentally, the average particle size as used herein is the D50 value measured by a laser diffraction particle size distribution analyzer.

The average particle size of less than 0.5 μm is not preferable in that the filler will undergo aggregation, resulting in rendering an insufficient effect.

The filler that can be used in the present disclosure is not limited, and examples thereof can include at least one organic filler selected from an aramid fiber, a polyphenyl ester, polyphenylene sulfide, polyimide, polyether ether ketone, polyphenylene, polyamide, and a wholly aromatic polyester resin; and at least one inorganic filler selected from ceramics, talc, mica, aluminum oxide, zinc oxide, tin oxide, titanium oxide, silicon oxide, calcium carbonate, calcium oxide, magnesium oxide, potassium titanate, a glass fiber, a glass chip, a glass bead, silicon carbide, calcium fluoride, boron nitride, barium sulfate, molybdenum disulfide, and a potassium carbonate whisker. Two or more of these may be combined for use.

The shape of the filler is not limited, but is particularly preferably spherical. A spherical shape thereof facilitates uniform processing of filler upon drilling and reduces a small specific surface area and a low transmission loss of the filler, which is preferable in these respects.

Among these, it is particularly preferable to use silica, and it is most preferable to use a spherical silica particle.

The spherical silica particle refers to a particle, the shape of which is close to a perfect sphere. Specifically, the sphericity is preferably 0.80 or more, more preferably 0.85 or more, still more preferably 0.90 or more, and most preferably 0.95 or more. The sphericity is calculated by taking a photograph of the particle with an SEM and calculating a value from an area and an perimeter of the particle observed, by formula: (sphericity)={4π×(area)/(perimeter)2}. The closer the sphericity is to 1, the closer the particle is to a perfect sphere. Specifically, an average value measured for 100 particles is adopted using an image processing device (FPIA-3000 manufactured by Spectris PLC).

The spherical silica particle used in the present disclosure preferably has D90/D10 of 2 or more (preferably 2.3 or more, 2.5 or more) and D50 of 10 μm or less when integrating its volume from the smallest particle size. Furthermore, D90/D50 is preferably 1.5 or more (more preferably 1.6 or more). D50/D10 is preferably 1.5 or more (more preferably 1.6 or more). Furthermore, D50 is more preferably 5 μm or less. A spherical silica particle with a small particle size can enter a gap between spherical silica particles with a large particle size, making it possible to achieve excellent filling property and high flowability. In particular, a particle size distribution of the particle with a high frequency of small particle sizes, is preferable compared to a Gaussian curve. The particle size can be measured by a laser diffraction-scattering type particle size distribution analyzer. Since coarse particles make it difficult to form a thin sheet, the coarse particles having a particle size of a predetermined size or more are preferably removed using a filter or the like.

The spherical silica particle preferably has a water absorption of 1.0% or less and more preferably 0.5% or less. The water absorption is based on the mass of the silica particles when dry. The water absorption is measured by allowing a sample to be left standing in a dry state at 40° C. and 80% RH for 1 hour, measuring water generated by heating at 200° C. using a Karl Fischer moisture meter, and calculating the water absorption.

Also, the fluororesin sheet may be heated at 600° C. for 30 minutes in an air atmosphere to burn off the fluororesin and extract spherical silica particles then to measure each of the above parameters of the spherical silica particles, using the aforementioned method as well.

The silica particle has been surface-treated. The preliminary surface treatment enables silica particles to be inhibited from its aggregation and allows the silica particles to be favorably dispersed in the resin composition. The silica particle is also preferable in terms of being capable of allowing the ratio of (the dielectric loss tangent of the filler measured at 10 GHz)/(a surface area of the filler (m²/g)) to stay within a predetermined range.

The surface treatment can be carried out by appropriately selecting the type of surface-treating agent and the amount used for the treatment so that the ratio of (the dielectric loss tangent of the filler measured at 10 GHz)/(a surface area of the filler (m²/g)) falls within a predetermined range.

The surface treatment is not limited, and any known surface treatment can be employed. Specific examples thereof include treatment with silane coupling agents such as epoxy silane having a reactive functional group, amino silane, isocyanate silane, vinyl silane, acrylic silane, hydrophobic alkyl silane, phenyl silane, and fluorinated alkyl silane, plasma processing, and fluorination treatment.

Examples of the silane coupling agent include epoxy silanes such as γ-glycidoxypropyltriethoxysilane and β-(3,4-epoxycyclohexyl)ethyltrimethoxysilane, amino silanes such as aminopropyltriethoxysilane and N-phenylaminopropyltrimethoxysilane, isocyanate silane such as 3-isocyanatepropyltrimethoxysilane, vinyl silanes such as vinyltrimethoxysilane, and acrylic silanes such as acryloxytrimethoxysilane.

The spherical silica particle to be used may be a commercially available silica particle that satisfy the properties described above. Examples of the commercially available silica particle include DENKA FUSED SILICA FB Grade (manufactured by Denka Company Limited), Denka FUSED SILICA SFP Grade (manufactured by Denka Company Limited), EXELICA (manufactured by Tokuyama Corporation), a high-purity synthetic spherical silica particle ADMAFINE (manufactured by Admatechs Co., Ltd.), ADMANANO (manufactured by Admatechs Co., Ltd.), and ADMAFUSE (manufactured by Admatechs Co., Ltd.).

The value of (the dielectric loss tangent of the filler measured at 10 GHz)/(a surface area of the filler (m²/g)) can be adjusted by a filler shape, a filler size, with surface treatment or without surface treatment, and the like. More specifically, it is preferable to use a spherical silica particle of a predetermined size as the aforementioned spherical silica particle, which is further subjected to surface treatment. The type of surface-treating agent used upon surface treatment also affects the parameter described above. More specifically, the spherical silica particle is particularly preferably those that are surface treated with aminopropyltriethoxysilane, aminosilane, vinylsilane, hydrophobic alkylsilane, phenylsilane, 3-mercaptopropylsilane, 3-acryloxypropylsilane, 3-methacryloxypropylsilane, p-styrylsilane, silylpropylsuccinic anhydride, 3-isocyanatopropylsilane, 2-(3,4-epoxycyclohexyl) ethylsilane, and the like. The surface treatment using these silane coupling agents allows a polar functional group present on a filler surface to react and reduces the amount of a polar functional group, resulting in excellent electrical characteristics.

The filler is preferably contained in a proportion of 50% by weight or more relative to a sheet weight. Such an amount of filler compounded renders thermal expansion low while maintaining a low dielectric constant and a low loss. The amount of filler compounded is more preferably 53% by weight or more and still more preferably 56% by weight or more. The upper limit of the amount of the filler compounded is not limited, but it is preferably 68% by weight or less and still more preferably 65% by weight or less.

### Fluororesin

The composition of the present disclosure contains a fluororesin. The fluororesin has low dielectric properties and can be suitably used for the purposes of the present disclosure.

The fluororesin as can be used in the present disclosure is not limited, but examples thereof include polytetrafluoroethylene (PTFE), a tetrafluoroethylene [TFE]/hexafluoropropylene [HFP] copolymer [FEP], a TFE/alkyl vinyl ether copolymer [PFA], a TFE/HFP/alkyl vinyl ether copolymer [EPA], a TFE/chlorotrifluoroethylene [CTFE] copolymer, a TFE/ethylene copolymer [ETFE], polyvinylidene difluoride [PVdF], and tetrafluoroethylene with a molecular weight of 300,000 or less [LMW-PTFE]. The fluororesin may be used singly or two or more thereof may be mixed and used. From the viewpoint of the low dielectric properties, the fluororesin is particularly preferably polytetrafluoroethylene resin (PTFE). The PTFE resin preferably is fibrillatable. The PTFE resin being fibrillatable means a PTFE resin that can be extruded in paste form from unsintered polymer powder thereof.

The PTFE may be modified polytetrafluoroethylene (hereinafter referred to as modified PTFE), homopolytetrafluoroethylene (hereinafter referred to as homo-PTFE), or a mixture of modified PTFE and homo-PTFE. Incidentally, from the viewpoint of maintaining favorable moldability of polytetrafluoroethylene, the content proportion of the modified PTFE in polymeric PTFE is preferably 10% by weight or more and 98% by weight or less and more preferably 50% by weight or more and 95% by weight or less. The homo-PTFE is not limited, and those disclosed in Japanese Patent Laid-Open No. 53-60979, Japanese Patent Laid-Open No. 57-135, Japanese Patent Laid-Open No. 61-16907, Japanese Patent Laid-Open No. 62-104816, Japanese Patent Laid-Open No. 62-190206, Japanese Patent Laid-Open No. 63-137906, Japanese Patent Laid-Open No. 2000-143727, Japanese Patent Laid-Open No. 2002-201217, International Publication No. WO2007/046345, International Publication No. WO2007/119829, International Publication No. WO2009/001894, International Publication No. WO2010/113950, International Publication No. WO2013/027850, and the like, can be suitably used. Among them, preferred are homo-PTFE having high stretchability and disclosed in Japanese Patent Laid-Open No. 57-135, Japanese Patent Laid-Open No. 63-137906, Japanese Patent Laid-Open No. 2000-143727, Japanese Patent Laid-Open No. 2002-201217, International Publication No. WO2007/046345, International Publication No. WO2007/119829, International Publication No. WO2010/113950, and the like.

The modified PTFE is composed of TFE and a monomer other than TFE (hereinafter referred to as a modifying monomer). Examples of the modified PTFE includes, but are not limited to, modified PTFE uniformly modified with the modifying monomer, modified PTFE modified at the beginning of a polymerization reaction, modified PTFE modified at the end of a polymerization reaction, and the like. The modified PTFE is preferably a TFE copolymer obtained by subjecting a small amount of monomer other than TFE to a polymerization together with TFE within a range that does not significantly impair the properties of a TFE homopolymer. The modified PTFE for use may be suitably, for example, those disclosed in Japanese Patent Laid-Open No. 60-42446, Japanese Patent Laid-Open No. 61-16907, Japanese Patent Laid-Open No. 62-104816, Japanese Patent Laid-Open No. 62-190206, Japanese Patent Laid-Open No. 64-1711, Japanese Patent Laid-Open No. 2-261810, Japanese Patent Laid-Open No. 11-240917, Japanese Patent Laid-Open No. 11-240918, International Publication No. WO 2003/033555, International Publication No. WO 2005/061567, International Publication No. WO 2007/005361, International Publication No. WO2011/055824, International Publication No. WO2013/027850, and the like. Among these, preferred are the modified PTFE having high stretchability and disclosed in Japanese Patent Laid-Open No. 61-16907, Japanese Patent Laid-Open No. 62-104816, Japanese Patent Laid-Open No. 64-1711, Japanese Patent Laid-Open No. 11-240917, International Publication No. WO2003/033555, International Publication No. WO2005/061567, International Publication No. WO2007/005361, International Publication No. WO2011/055824, and the like.

The modified PTFE includes a TFE unit based on TFE and a modifying monomer unit based on the modifying monomer. The modifying monomer unit is a portion of the molecular structure of the modified PTFE and is derived from the modifying monomer. The modified PTFE preferably contains a modifying monomer unit in an amount of 0.001 to 0.500% by weight and more preferably 0.01 to 0.30% by weight, of the total monomer unit. The total monomer unit is a portion derived from all monomers in the molecular structure of the modified PTFE.

The modifying monomer is not limited as long as it can be copolymerized with TFE, and examples thereof include a perfluoroolefin such as hexafluoropropylene (HFP); a chlorofluoroolefin such as chlorotrifluoroethylene (CTFE); hydrogen-containing fluoroolefins such as trifluoroethylene and vinylidene difluoride (VDF); perfluorovinyl ether; a perfluoroalkylethylene (PFAE), and ethylene. The modifying monomer to be used may be one type or a plural types thereof.

The perfluorovinyl ether is not limited, and examples thereof include an unsaturated perfluoro compound represented by the following general formula (1):

CF₂═CF—ORf (1)

wherein Rf represents a perfluoro organic group.

The perfluoro organic group as used herein is an organic group in which all hydrogen atoms bonded to carbon atoms are replaced with fluorine atoms. The perfluoro organic group may have an ether oxygen.

An example of the perfluorovinyl ether includes a perfluoro (alkyl vinyl ether) (PAVE) in which Rf in the general formula (1) described above is a perfluoroalkyl group having 1 to 10 carbon atoms. The number of carbon atoms in the perfluoroalkyl group is preferably 1 to 5. Examples of the perfluoroalkyl group in a PAVE include a perfluoromethyl group, a perfluoroethyl group, a perfluoropropyl group, a perfluorobutyl group, a perfluoropentyl group, and a perfluorohexyl group. A preferred PAVE is perfluoropropyl vinyl ether (PPVE) and perfluoromethyl vinyl ether (PMVE).

The perfluoroalkyl ethylene (PFAE) is not limited, and examples thereof include perfluorobutyl ethylene (PFBE) and perfluorohexyl ethylene (PFHE).

The modifying monomer in the modified PTFE is preferably at least one selected from the group consisting of HFP, CTFE, VDF, a PAVE, a PFAE and ethylene.

The fluororesin is preferably non-melt moldable. The phrase non-melt moldable means that a resin does not have sufficient flowability even when heated at its melting point or higher, and cannot be molded by melt forming techniques commonly used for resins. PTFE corresponds thereto.

In the present disclosure, it is preferable to use such a non-melt moldable fluororesin and form it into a fluororesin sheet by a forming method for fibrillating the fluororesin. The molding method will be described later.

The PTFE preferably has an SSG of 2.0 to 2.3. The use of such PTFE facilitates a PTFE film having high strength (cohesion strength and puncture strength per unit thickness) to be obtained. PTFE with a large molecular weight has long molecular chains, making it less likely to form a structure of molecular chains regularly arranged. In this case, an amorphous portion elongates, resulting in an increase in the degree of entanglement between molecules. It is considered that the high degree of entanglement between molecules is less likely to allow a PTFE film to deform under an applied load and therefore to exhibit excellent mechanical strength. Also, using PTFE with a large molecular weight facilitates a PTFE film having a small average pore size to be obtained.

The lower limit of the SSG is more preferably 2.05 and still more preferably 2.1. The upper limit of the SSG is more preferably 2.25 and still more preferably 2.2.

The standard specific gravity [SSG] is measured by fabricating a sample in accordance with ASTM D-4895-89 and measuring the specific gravity of the obtained sample by a water displacement method.

In the present embodiment, the molecular weight (number-average molecular weight) of PTFE constituting PTFE powder is, for example, in the range of 200 to 12 million. The lower limit value of the molecular weight Of PTFE may be 3 million or 4 million. The upper limit value of the molecular weight of PTFE may be 10 million.

A method for measuring the number-average molecular weight of PTFE includes a method for determining it from the standard specific gravity and a measurement method based on dynamic viscoelasticity upon melting. The method for determining a number-average molecular weight from the standard specific gravity can be carried out by using a sample formed in accordance with ASTM D-4895-98 and a water displacement method in accordance with ASTM D-792. The measurement method employing dynamic viscoelasticity is explained, for example, by S. Wu in Polymer Engineering & Science, 1988, Vol. 28, 538, and in the same literature, 1989, Vol. 29, 273.

The PTFE preferably has a refractive index in the range of 1.2 to 1.6. With such a refractive index, the PTFE has a low dielectric constant, which is preferable in this regard. The refractive index can be adjusted to within the above-described range by a method of adjusting the polarizability or flexibility of the main chain or the like. The lower limit of the refractive index is more preferably 1.25, more preferably 1.30, and most preferably 1.32. The upper limit of the refractive index is more preferably 1.55, more preferably 1.50, and most preferably 1.45.

The refractive index is the value measured using a refractometer (Abbemat 300).

Also, the PTFE preferably has the maximum endothermic peak temperature (crystalline melting point) of 340±7° C.

The PTFE may be low-melting-point PTFE having the maximum peak temperature of 338° C. or lower on an endothermic curve on a crystalline melting curve measured by a differential scanning calorimeter, or high-melting-point PTFE having the maximum peak temperature of 342° C. or higher on an endothermic curve on a crystalline melting curve measured by a differential scanning calorimeter.

The low-melting-point PTFE is powder produced by a polymerization using an emulsion polymerization method, and has the maximum endothermic peak temperature (crystalline melting point), a dielectric constant (ε) of 2.08 to 2.2, and a dielectric loss tangent (tan δ) of 1.9×10⁻⁴ to 4.0×10⁻⁴. Examples of a commercially available product thereof include POLYFLON Fine Powder F201, F203, F205, F301, and F302 manufactured by Daikin Industries, Ltd.; CD090 and CD076 manufactured by Asahi Glass Co., Ltd.; and TF6C, TF62, and TF40 manufactured by Dupont De Nemours Inc.

The high melting point PTFE powder is also powder produced by a polymerization using an emulsion polymerization method, and has the above-described maximum endothermic peak temperature (crystalline melting point), a dielectric constant (ε) of 2.0 to 2.1, and a dielectric loss tangent (tan δ) of 1.6×10⁻⁴ to 2.2×10⁻⁴, which are overall low. Examples of a commercially available product thereof include POLYFLON Fine Powder F104 and F106 manufactured by Daikin Industries, Ltd.; CD1, CD141, and CD123 manufactured by Asahi Glass Co., Ltd.; and TF6 and TF65 manufactured by DuPont De Nemours Inc.

It is to be noted that an average particle size of powder in which both PTFE polymer particles have undergone secondary aggregation is usually preferably 250 to 2,000 μm. In particular, granulated powder obtained by granulation using a solvent is preferred from the viewpoint of improving flowability when filled in a mold upon preliminary forming.

The powdered PTFE that satisfies the aforementioned parameters can be obtained by conventional production methods. For example, it may be produced following the production methods described in International Publication No. WO2015/080291 and International Publication No. WO2012/086710.

### Composition

The composition of the present disclosure contains the aforementioned filler and fluororesin. The dielectric may contain a component other than the filler and fluororesin, or may consist only of the filler and fluororesin. The content of the component other than the filler and fluororesin is preferably 10% by weight or less.

The composition of the present disclosure preferably has a filler content of 70% by weight or less relative to the total amount of the composition. Containing the filler in such a range enables a coefficient of linear expansion to be reduced, which is preferable in terms of facilitation of moldability. The lower limit of the amount of filler compounded is not limited, but is preferably 40% by weight from the viewpoint of reducing the coefficient of linear expansion. The upper limit thereof is more preferably 68% by weight and still more preferably 65% by weight. The lower limit is more preferably 40% by weight and still more preferably 45% by weight.

The composition of the present disclosure preferably has a dielectric loss tangent at 10 GHz of 0.0001 to 0.0015 as the composition. Within such a range, the composition is preferable in terms of the composition, having a low loss.

Furthermore, the composition of the present disclosure may have a dielectric loss tangent at 80 GHz of 0.0001 to 0.0018 as the composition. It is preferable that the composition has a low dielectric loss tangent in such a wide frequency range and a low loss. Also, the low dielectric loss tangent at 80 GHz is preferable because it improves gain of millimeter wave antenna.

### Fluororesin Sheet

The fluororesin sheet of the present disclosure contains a fluororesin and a filler having the ratio of (the dielectric loss tangent of the filler measured at 10 GHz)/(a surface area of the filler (m²/g)) of 0.00001 to 0.00035.

The fluororesin sheet preferably has a thickness of less than 300 μm. The fluororesin sheet of the present disclosure even with a thin thickness can fully achieve its purpose. From such a viewpoint, the thickness is more preferably less than 200 μm and still more preferably less than 150 μm. Also, in a case in which the sheet can be processed to a thickness of 100 μm or less, if necessary, it can be widely applied to boards of various thicknesses, which is preferable.

The fluororesin sheet of the present disclosure preferably has a coefficient of linear expansion of 10 to 100 (ppm/° C.). Within the above range thereof, the fluororesin sheet is preferable in terms of having low shrinkage and excellent dimensional stability. The upper limit thereof is more preferably 90 and still more preferably 80. The lower limit thereof is more preferably 12 and still more preferably 15. The coefficient of linear expansion as used herein was determined by making a TMA measurement in tensile mode using a TMA-7100 (manufactured by Hitachi High-Tech Science Corporation), using a sheet cut to a length of 20 mm, width of 5 mm, and thickness of 150 μm as a sample piece, setting a chuck distance to 10 mm, and measuring the amount of sample displaced while applying a load of 49 mN, at −10 to 160° C. (rate of temperature rise of 2° C./min).

The fluororesin sheet of the present disclosure preferably has a rate of change in the dielectric constant in the temperature range of −50 to 150° C. of 0.025 or less, more preferably 0.023 or less, and still more preferably 0.021 or less. Within such a range of the rate, the sheet is preferable in terms of a little change in electrical characteristics depending on temperature, and obtaining stable performance when used in high-frequency printed circuit boards.

### Production Method of Fluororesin Sheet

The fluororesin sheet of the present disclosure can be obtained by mixing the aforementioned fluororesin particle and a filler to form the fluororesin into a sheet. The method for producing the sheet is not limited, but paste extrusion forming, powder rolling forming, and the like can be employed.

As described above, it is preferable to use a fluororesin that is non-melt-moldable as a fluororesin to be used in the fluororesin sheet of the present disclosure. When using such a fluororesin and forming it into a sheet, it is preferable to form it into a sheet by fibrillating powdered PTFE as a raw material.

It is preferable to use the powdered PTFE having a primary particle size of 0.05 to 10 μm. Using such powder has an advantage of excellent moldability and dispersibility. It is to be noted that the primary particle size as used herein is a value measured in accordance with ASTM D 4895.

The powdered PTFE contains a polytetrafluoroethylene resin having a secondary particle size of 500 μm or more in an amount of preferably 50% by mass or more and more preferably 80% by mass or more. The PTFE having a secondary particle size of 500 μm or more within the above range, has an advantage of being capable of fabricating a mixture sheet with high strength. Using the PTFE having a secondary particle size of 500 μm or more enables a mixture sheet with lower resistance and greater toughness to be obtained.

The lower limit of the secondary particle size is more preferably 300 μm and still more preferably 350 μm. The upper limit of the secondary particle size is more preferably 700 μm or less and still more preferably 600 μm or less. The secondary particle size can be determined, for example, by a sieving method or the like.

The powdered PTFE described above can provide a fluororesin sheet with higher strength and excellent homogeneity, so that an average primary particle size thereof is preferably 50 nm or more, more preferably 100 nm or more, still more preferably 150 nm or more, and particularly preferably 200 nm or more. The larger the average primary particle size of PTFE is, the more inhibited an increase in paste extrusion pressure upon paste extrusion forming using the powder will be, resulting in excellent moldability as well. The upper limit of the average primary particle size of PTFE is not limited, but it may be 500 nm. From the viewpoint of productivity in a polymerization process, it is preferably 350 nm.

The average primary particle size can be determined by preparing a calibration curve of a transmission of projected light of 550 nm relative to a unit length of an aqueous dispersion obtained by using an aqueous dispersion of PTFE obtained by polymerization and adjusting its polymer concentration to 0.22% by mass, and an average primary particle size determined by measuring an unidirectional diameter of the particle observed in a photograph of the particle by a transmission electron microscope, and then measuring the transmission of the aqueous dispersion to be measured, based on the calibration curve.

The PTFE to be used in the present disclosure may have a core-shell structure. An example of the PTFE having a core-shell structure includes modified polytetrafluoroethylene which contains a core of high molecular weight polytetrafluoroethylene in the particle and a shell of lower molecular weight polytetrafluoroethylene or modified polytetrafluoroethylene. An example of such modified polytetrafluoroethylene includes the polytetrafluoroethylene described in Japanese Translation of PCT International Application Publication No. 2005-527652.

Specific methods of paste extrusion forming and powder rolling forming are not limited, and a general method will be described below.

### Paste Extrusion Forming

A method for producing the sheet may include the steps of (1a) mixing PTFE powder obtained by using a hydrocarbon surfactant with an auxiliary agent for extrusion, (1b) subjecting the mixture obtained to paste extrusion forming, (1c) rolling the extrudate obtained by extrusion forming, (1d) drying the rolled sheet, and (1e) sintering the dried sheet to obtain a formed article. The paste extrusion forming may also be performed by adding a conventionally and publicly known additive such as a pigment or a filler to the PTFE powder.

The auxiliary agent for extrusion is not limited, and any publicly known agent may be used. Examples thereof include hydrocarbon oil and the like.

### Powder Rolling Forming

The sheet can also be formed by powder rolling forming. The powder rolling forming is a method for applying shear force to resin powder followed by fibrillation thereof, and thus forming it into a sheet. This method may include the step of sintering the sheet thereafter to obtain a formed article.

More specifically, the sheet can be obtained by a production method thereof, having step (1) of applying shear force while mixing a raw material composition containing a fluororesin and a filler,
step (2) of forming the mixture obtained by step (1) into a bulk form, and
step (3) of rolling the mixture in bulk form obtained by step (2) into a sheet. It is to be noted that in the case of obtaining a sheet by such powder rolling forming, it is preferable to mix only a fluororesin particle and an inorganic filler to form the sheet.

### Laminate

The sheet resin composition of the present disclosure can be used as a sheet for printed wiring boards by stacking it with other substrate.

The present disclosure also provides a copper-clad laminate characterized in that copper foil is adhered to one or both sides of the aforementioned fluororesin film. As described above, the film containing the fluororesin of the present disclosure is particularly suitable for use in printed wiring board applications, and therefore can be suitably used as such a copper-clad laminate.

The copper foil preferably has an Rz of 1.6 μm or less. That is, the fluororesin composition of the present disclosure also has excellent adhesiveness to copper foil with a high smoothness of Rz of 1.6 μm or less.

Furthermore, the copper foil is only required to have an Rz value of 1.6 μm or less on at least a surface in adhesion with the aforementioned fluororesin film, and the other surface is not limited in terms of the Rz value. The Rz is the sum of a value of the highest portion (maximum peak height: Rp) and a value of the deepest portion (maximum valley depth: Rv). The surface roughness is a ten-point average roughness stipulated in JIS-B0601. The Rz as used herein is the value measured using a surface roughness meter (product name: SURFCOM 470A, manufactured by Tokyo Seimitsu Co., Ltd.) with a measurement length of 4 mm.

A thickness of the copper foil is not limited, but is preferably in the range of 1 to 100 μm, more preferably in the range of 5 to 50 μm, and still more preferably in the range of 9 to 35 μm.

The copper foil is not limited, and specific examples thereof include rolled copper foil and electrolytic copper foil.

The copper foil having an Rz of 1.6 μm or less is not limited, and commercially available products can be used. An example of commercially available copper foil having an Rz of 1.6 μm or less includes electrolytic copper foil CF-T9DA-SV-18 (thickness 18 μm/Rz 0.85 μm) (manufactured by Fukuda Metal Foil Powder Co., Ltd.).

The copper foil may also be surface-treated in order to increase its adhesion strength with the fluororesin film of the present disclosure.

The surface treatment is not limited, but may be silane coupling treatment, plasma processing, corona processing, UV processing, electron beam processing, and the like, and a reactive functional group of the silane coupling agent is not limited, and from the viewpoint of adhesiveness to a resin substrate, the reactive functional group preferably has at least one selected from an amino group, a (meth)acrylic group, a mercapto group, and an epoxy group at the end. Also, a hydrolyzable group is not limited, but examples thereof include alkoxy groups such as a methoxy group and an ethoxy group. The copper foil to be used in the present disclosure may also have a rust-proof layer (such as an oxide film such as chromate), a heat-resistant layer, and the like.

Surface-treated copper foil having a surface-treating layer treated with the silane compound on a surface of the copper foil can be produced by preparing a solution containing the silane compound and then subjecting the copper foil to surface treatment with the solution.

The copper foil may have a roughening treatment layer on a surface from the viewpoint of enhancing adhesiveness to a resin substrate.

Incidentally, when there is a risk that the roughening treatment will lower the performance required in the present disclosure, the amount of roughened particles electrodeposited on a surface of the copper foil may be reduced, if necessary, or an embodiment of not carrying out the roughening treatment may be adopted.

From the viewpoint of improving various properties, one or more layers selected from the group consisting of a heat treatment layer, an rust-proof processing layer, and a chromate processing layer may be arranged between copper foil and the surface-treating layer. These layers may be a single layer or a plurality of layers.

The copper-clad laminated board may further have a layer other than the copper foil and the fluororesin film.

The layer other than the copper foil and the fluororesin film is preferably at least one selected from the group consisting of polyimide, modified polyimide, a liquid crystal polymer, polyphenylene sulfide, a cycloolefin polymer, polystyrene, an epoxy resin, bismaleimide, polyphenylene oxide, modified polyphenylene ether, polyphenylene ether, and polybutadiene.

The layer other than the copper foil and fluororesin film is not limited as long as it is composed of the aforementioned resin. Also, the layer other than the copper foil and the fluororesin film preferably has a thickness within the range of 12.5 to 260 μm.

The copper-clad laminated board of the present disclosure may have a copper layer formed on one or both sides of a roll film. Examples of a method for forming the copper layer include a method for stacking (adhering) copper foil on a surface of the roll film, a vapor deposition method, a plating method, and the like. An example of the method for stacking copper foil includes a method using heat press. An example of a heat press temperature upon heat press includes a temperature between the melting point of the dielectric film −150° C. and the melting point of the dielectric film +40° C. A heat press time is, for example, 1 to 30 minutes. A heat press pressure may be 0.1 to 10 MPa. The copper-clad laminated board can be produced by the above methods.

The use of the copper-clad laminated board of the present disclosure is not limited, and it is used as a circuit board. A printed circuit board is a platy component for electrically connecting an electronic component such as a semiconductor and a capacitor chip, and simultaneously arranging and fixing them in a limited space. A configuration of a printed circuit board formed from the present copper-clad laminate is not limited. The printed circuit board may be any of a rigid board, a flexible board, or a rigid-flexible board. The printed circuit board may be any of a single-sided board, a double-sided board, or a multi-layered board (such as a built-up board). In particular, it is suitably used for a flexible board or a rigid board. It is particularly suitable for use as a printed circuit board for high frequencies of 10 GHz or higher.

The circuit board is not limited, and can be produced by a general method using the aforementioned copper-clad laminate board.

A laminate for circuit boards is also a laminate characterized in that it has a copper foil layer, the aforementioned fluororesin film, and a substrate layer. The substrate layer is not limited, but preferably has a fabric layer composed of glass fibers and a resin film layer.

The fabric layer composed of glass fibers is a layer composed of glass cloth, a glass nonwoven fabric, or the like.

Commercially available glass cloth can be used, and it is preferably cloth treated with a silane coupling agent in order to enhance its affinity with a fluororesin. Examples of a glass cloth material include E glass, C glass, A glass, S glass, D glass, NE glass, and glass with a low dielectric constant, and the E glass, S glass, and NE glass are preferable in terms of their facilitation of availability. Weave of fibers may be plain weave or twill weave. A thickness of the glass cloth is usually 5 to 90 μm, preferably 10 to 75 μm, but it is preferable to use glass cloth that is thinner than a fluororesin film to be used.

The laminate may be a laminate in which a glass nonwoven fabric is used as a fabric layer composed of glass fibers. The glass nonwoven fabric is fabric in which glass staple fibers are fixed with a small amount of a binder compound (resin or inorganic substance), or fabric in which glass staple fibers are entangled without using a binder compound to maintain its shape, and commercially available products can be used. The diameter of the glass staple fiber is preferably 0.5 to 30 μm, and the fiber length is preferably 5 to 30 mm.

Specific examples of the binder compound include resins such as an epoxy resin, an acrylic resin, cellulose, polyvinyl alcohol, and a fluororesin, and an inorganic substance such as a silica compound. The amount of binder compound used is usually 3 to 15% by mass of the glass staple fiber. Examples of a material for the glass staple fiber include E glass, C glass, A glass, S glass, D glass, NE glass, and glass with a low dielectric constant. A thickness of the glass nonwoven fabric is usually 50 to 1,000 μm and preferably 100 to 900 μm. It is to be noted that the thickness of the glass nonwoven fabric as used herein refers to the value measured in accordance with JIS P8118:1998 using a digital gauge DG-925 (load 110 grams, surface diameter 10 mm) manufactured by ONO SOKKI CO., LTD. In order to enhance the affinity with a fluororesin, the glass nonwoven fabric may be subjected to treatment with a silane coupling agent.

Most glass nonwoven fabrics have a very high porosity of 80% or more, so that it is preferable to use fabric thicker than a sheet composed of a fluororesin, compress it by pressure, and then use it.

The fabric layer composed of the glass fibers may be a layer stacked with glass cloth and a glass nonwoven fabric. This allows the properties of each to be combined to obtain optimal properties.

The fabric layer composed of the glass fiber may be in the form of a prepreg impregnated with resin.

The laminate may be a laminate in which a fabric layer composed of glass fibers and a fluororesin film have been adhered at the interface thereof, wherein the fabric layer composed of glass fibers may be partially or totally impregnated with the fluororesin film.

Furthermore, the laminate may be a laminate in which fabric composed of glass fibers is impregnated with a fluororesin composition to produce a prepreg. The prepreg thus obtained may be stacked with the fluororesin film of the present disclosure. In this case, a fluororesin composition to be used upon production of the prepreg is not limited, and the fluororesin film of the present disclosure can be used.

A resin film to be used as the substrate layer is preferably a heat-resistant resin film or a thermosetting resin film. Examples of the heat-resistant resin film include polyimide, modified polyimide, a liquid crystal polymer, and polyphenylene sulfide. Examples of the thermosetting resin include an epoxy resin, bismaleimide, polyphenylene oxide, modified polyphenylene ether, polyphenylene ether, and polybutadiene.

The heat-resistant resin film and the thermosetting resin film may contain a reinforcing fiber. The reinforcing fiber is not limited, but for example, glass cloth, particularly those of low dielectric type, are preferable.

The properties of the heat-resistant resin film and the thermosetting resin film, such as the dielectric properties, coefficient of linear expansion, and water absorption rate, are not limited, but for example, the dielectric constant at 20 GHz is preferably 3.8 or less, more preferably 3.4 or less, and still more preferably 3.0 or less. The dielectric loss tangent at 20 GHz is preferably 0.0030 or less, more preferably 0.0025 or less, and still more preferably 0.0020 or less. The coefficient of linear expansion is preferably 100 ppm/° C. or less, more preferably 70 ppm/° C. or less, and still more preferably 40 ppm/° C. or less. The water absorption rate is preferably 1.0% or less, more preferably 0.5% or less, and still more preferably 0.1% or less.

The present disclosure provides a composition for obtaining a fluororesin sheet having excellent performance in terms of a low dielectric constant, a low loss, and low thermal expansion, a fluororesin sheet made into a thin film, and a method for producing the same.

The present disclosure is a composition characterized in that it comprises a fluororesin and a filler having a ratio of (a dielectric loss tangent of the filler measured at 10 GHz)/(a surface area of the filler (m²/g)) of 0.00001 to 0.00035.

The fluororesin is preferably a polytetrafluoroethylene resin.

The fluororesin is preferably non-melt moldable.

The polytetrafluoroethylene resin preferably has an SSG of 2.0 to 2.3.

The polytetrafluoroethylene resin preferably has a refractive index of 1.2 to 1.6.

The fluororesin preferably has a primary particle size of 0.05 to 10 μm.

The fluororesin preferably has a particle size at a cumulative volume of 50% of 0.05 to 40 μm.

The filler is preferably a silica particle.

The filler preferably has a filler content of 50 wt % or more relative to the total amount of the composition.

The filler preferably has an average particle size of 0.5 to 250 μm.

The filler is preferably a filler, a surface of which is coated with a silane coupling agent.

The composition preferably has a dielectric loss tangent value at 10 GHz of 0.0015 or less.

The present disclosure is also a fluororesin sheet comprising a composition that contains a fluororesin and a filler having a ratio of (the dielectric loss tangent of the filler measured at 10 GHz)/(a surface area of the filler (m²/g)) of 0.00001 to 0.00035.

The fluororesin sheet preferably has a thickness of 5 to 250 μm.

The present disclosure is also a method for producing the aforementioned fluororesin sheet, characterized in that it comprises a step of mixing a fluororesin particle and the filler to form a film.

The method for producing the fluororesin sheet preferably comprises mixing only the fluororesin particle and an inorganic filler to form the film without addition of other components.

The present disclosure is also a copper-clad laminate having copper foil and the aforementioned fluororesin film as essential layers.

The present disclosure is also a circuit board characterized by having the copper-clad laminate described above.

The fluororesin sheet obtained by the composition of the present disclosure has excellent performance in terms of a low dielectric constant, a low loss, and low thermal expansion. Also, the sheet can be made thin.

### EXAMPLES

The present disclosure will be specifically described below based on Examples. In the following examples, “part” and “%” represent “parts by mass” and “% by mass”, respectively, unless otherwise specified.

The following silica was used in the following Examples and Comparative Examples.

TABLE 1

| | | Amount | | | Specific | Df/ |
|---|---|---|---|---|---|---|
| | Silane coupling | of | | | surface | Specific |
| | agent surface | surface | | D50 | areas | Surface |
| Type of silica | treatment | treatment | Df | (μm) | (m2/g) | area |
| SC6500-SQ | Spherical silica surface | | 0.0005 | 2.1 | 1.7 | 0.00029 |
| (manufactured by | treated with silane | | | | | |
| Admatechs Co., Ltd.) | coupling agent | | | | | |
| SC 4500-5Q | Spherical silica surface | | 0.0009 | 0.9 | 4.3 | 0.00021 |
| (manufactured by | treated with silane | | | | | |
| Admatechs Co., Ltd.) | coupling agent | | | | | |
| 5SV-C23 (manufactured | Vinyl silane | | 0.0009 | 0.5 | 6.1 | 0.00015 |
| by Admatechs Co., Ltd.) | | | | | | |
| 5GF-C2 (manufactured | Hexyl silane | | 0.0009 | 0.5 | 6.1 | 0.00015 |
| by Acmatechs Co., Ltd.) | | | | | | |
| 5SP-C3 (manufactured | Phenyl silane | | 0.0008 | 0.5 | 6.1 | 0.00013 |
| by Admatechs Co., Ltd.) | | | | | | |
| 5SX-C23 (manufactured | Phenyl amino silane | | 0.0009 | 0.5 | 6.1 | 0.00014 |
| by Admatechs Co., Ltd. | | | | | | |
| SC2500-SQ | Aminopropyl silane | 1 wt % | 0.0007 | 0.5 | 6.1 | 0.00012 |
| (manufactured by | | | | | | |
| Admatechs Co., Ltd.) + | | | | | | |
| aminopropyl | | | | | | |
| SC6500-SQ | Aminopropyl silane | 1 wt % | 0.0004 | 2.1 | 1.7 | 0.00023 |
| (manufactured by | | | | | | |
| Admatechs Co., Ltd.) + | | | | | | |
| aminopropyl | | | | | | |
| SFP-20M (manufactured | None | 0 wt % | 0.0057 | 0.22 | 11.1 | 0.00051 |
| by Denka Company | | | | | | |
| Limited) | | | | | | |
| SC2500-SQ | Spherical silica surface | | 0.0026 | 0.5 | 6.1 | 0.00043 |
| (manufactured by | treated with silane | | | | | |
| Admatechs Co., Ltd.) | coupling agent | | | | | |
| 5SE-C1 (manufactured | Epoxy silane | | 0.0032 | 0.5 | 6.1 | 0.00052 |
| by Admatechs Co., Ltd.) | | | | | | |
| ZA-30 (manufactured by | None | 0 wt % | 0.0015 | 5.6 | 5.5 | 0.00153 |
| Tatsumori Ltd.) | | | | | | |
| ZA-30 (manufactured by | Phenyl + | 1 wt % | 0.0004 | 5.8 | 5.5 | 0.00040 |
| Tatsumori Ltd.) | aminoethylaminopropyl | | | | | |

In the table, the term “phenyl+amino” in ZA-30 is a mixture of phenyltrimethoxysilane and aminoethylaminopropyltrimethoxysilane in a ratio of 9:1.

Each sample in Table 1 above was evaluated based on the following method.

### Df (Dielectric Loss Tangent) of Filler

The dielectric loss tangent of the filler measured at 10 GHz was measured using a cylindrical cavity resonator and a network analyzer, with a filler powder sample filled into a quartz tube and loaded into the resonator. The properties of the resonator (resonant frequency and Q value) were acquired before and after the sample was intercalated, and the dielectric loss tangent was calculated from the results.

This estimation method complies with the Japanese Industrial Standards JIS 2565 Measuring methods for ferrite cores for microwave device.

### D50

Each sample was measured using a laser diffraction particle size distribution analyzer.

### Specific Surface Area of Filler

The specific surface area is a value based on a BET method, and it was measured using a “Macsorb HM model-1208” (manufactured by Mountech Co. Ltd.).

### Example 1

### Sheet Fabrication Method 1 (Paste Extrusion Forming)

The predetermined amounts of PTFE powder (average particle size: 500 μm, apparent density: 460 g/L, and standard specific gravity: 2.17) and silica were weighed out in the proportions shown in Table 1 and mixed in a mixer in the presence of dry ice. The temperature during mixing was −10° C. or lower.

Oil (IP Solvent 2028) was added to the obtained mixed powder in a concentration of 18 to 23 wt %, mixed, and aged for about 5 hours.

The aged composition was preliminarily formed under the condition of a pressure of 3 MPa, and the formed article preliminarily formed was extruded under conditions of 40° C. and 50 mm/min. to obtain an extrusion sample. The extrusion sample was rolled with two rolls to obtain a sample with a thickness of 125 μm. The sample was dried at 200° C. for 2 hours and sintered at 360° C. for 15 minutes to obtain a sheet. Furthermore, the pressure of the twin rolls was adjusted to fabricate a sample with a thickness of 30 μm, and occurrence or nonoccurrence of holes or tears was observed.

Each sample obtained was evaluated based on the following criteria.

### Sheet Df

The Df was measured at 25° C., 10 GHz, and 80 GHz using a split-cylinder type dielectric constant/dielectric loss tangent measurement apparatus (manufactured by EM Labs, Inc.).

### Coefficient of Linear Expansion

The coefficient of linear expansion was determined by making a TMA measurement in tensile mode using a TMA-7100 (manufactured by Hitachi High-Tech Science Corporation), using a sheet cut to a length of 20 mm, width of 5 mm, and thickness of 150 μm as a sample piece, setting a chuck distance to 10 mm, and measuring the amount of sample displaced while applying a load of 49 mN, at 0 to 150° C. (rate of temperature rise of 2° C./min).

### Film Made Thin to 30 μm

In the compositions shown in Table 2 below, the sheets with a composition of PTFE/silica=40/60, which could be formed to a thickness of 30 μm without holes or tears, were ranked and marked as “Good”, and the films that could not be formed were ranked and marked as “Poor”.

The results are shown in Table 2.

TABLE 2

| | | PTFE/silica = 50/50 | | PTFE/silica = 40/60 | | |
|---|---|---|---|---|---|---|
| | | (mass ratio) | | (mass ratio) | | |
| | | | Coefficient | | Coefficient | Film |
| | | | of linear | | of linear | made |
| | | Sheet | expansion | Sheet | expansion | thin to |
| | Type of silica | Df | (ppm/° C.) | Df | (ppm/° C.) | 30 μm |
| Example 1 | SC6500-SQ | 0.0004 | 66 | 0.0004 | 54 | Good |
| Example 2 | SC4500-SQ | 0.0006 | 60 | | | Good |
| Example 3 | 5SV-C23 | 0.0015 | 82 | | | Good |
| Example 4 | 5GF-C2 | 0.0015 | 61 | | | Good |
| Example 5 | 5SP-C3 | 0.0007 | 80 | | | Good |
| Example 6 | 5SX-C23 | 0.0012 | 62 | | | Good |
| Example 7 | SC2500-SQ + | 0.0006 | 63 | 0.0010 | 25 | Good |
| | aminopropyl | | | | | |
| Example 8 | SC6500-SQ + | 0.0008 | 63 | 0.0006 | 31 | Good |
| | aminopropyl | | | | | |
| Comparative | SFP-20M | 0.0025 | 72 | | | Good |
| Example 1 | | | | | | |
| Comparative | SC2500-SQ | 0.0019 | 63 | 0.0022 | 31 | Good |
| Example 2 | | | | | | |
| Comparative | 5SE-C1 | 0.0020 | 60 | | | Good |
| Example 3 | | | | | | |
| Comparative | ZA-30 | 0.0063 | 43 | 0.0078 | 35 | Poor |
| Example 4 | | | | | | |
| Comparative | ZA-30 + phenyl + | 0.0019 | 46 | 0.0025 | 34 | Poor |
| Example 5 | aminoethylaminopropyl | | | | | |

The results described above shows that the fluororesin sheet of the present disclosure has excellent performance in terms of the low dielectric constant, low loss, and low thermal expansion. Furthermore, the Df at 80 GHz of the sheet with the PTFE/silica=40/60 (mass ratio) of Example 8 is 0.0008, exhibiting excellent performance even at 80 GHz.

For the sheets with the PTFE/silica=40/60 of Examples 1 and 8 above, the rate of change in the dielectric constant in the temperature range of −50 to 150° C. was measured based on the following method. The results are shown in Table 3.

### Measurement Method of Rate of Change in Dielectric Constant in Temperature Range of −50 to 150° C.

Using a split-cylinder type dielectric constant.dielectric loss tangent measurement apparatus (manufactured by EM Labs, Inc.), the Dk at 10 GHz was measured at 10° C. intervals from −50° C. to 150° C.

The rate of change from −50° C. to 150° C. was calculated from the difference between the maximum value and minimum value of the Dk values measured.

TABLE 3

| | Rate of change in dielectric constant in temperature range |
|---|---|
| | of −50 to 150° C. |
| Example 1 | 0.023 |
| Example 8 | 0.021 |

The results in Table 3 clearly show that the fluororesin sheet of the present disclosure has a small rate of change in the dielectric constant in the temperature range of −50 to 150° C.

### INDUSTRIAL APPLICABILITY

Particularly the fluororesin sheet of the present disclosure can be suitably used for high-frequency printed circuit boards.

1. A composition comprising a fluororesin and a filler having a ratio (a dielectric loss tangent of the filler measured at 10 GHz)/(a surface area of the filler (m²/g)) of 0.00001 to 0.00035.

2. The composition according to claim 1, wherein the fluororesin is a polytetrafluoroethylene resin.

3. The composition according to claim 1, wherein the fluororesin is not melt moldable.

4. The composition according to claim 2, wherein the polytetrafluoroethylene resin has an SSG of 2.0 to 2.3.

5. The composition according to claim 2, wherein the polytetrafluoroethylene resin has a refractive index of 1.2 to 1.6.

6. The composition according to claim 1, wherein the fluororesin has a primary particle size of 0.05 to 10 μm.

7. The composition according to claim 1, wherein the fluororesin has a particle size at a cumulative volume of 50% of 0.05 to 40 μm.

8. The composition according to claim 1, wherein the filler is a silica particle.

9. The composition according to claim 1, wherein content of the filler relative to a total amount of the composition is 50 wt % or more.

10. The composition according to claim 1, wherein the filler has an average particle size of 0.5 to 250 μm.

11. The composition according to claim 1, wherein a surface of the filler is coated with a silane coupling agent.

12. The composition according to claim 1, having a dielectric loss tangent value at 10 GHz of 0.0015 or less.

13. A fluororesin sheet comprising a composition that contains a fluororesin and a filler having a ratio (a dielectric loss tangent of the filler measured at 10 GHz)/(a surface area of the filler (m²/g)) of 0.00001 to 0.00035.

14. The fluororesin sheet according to claim 13, having a thickness of 5 to 250 μm.

15. A method for producing the fluororesin sheet according to claim 13, comprising mixing a fluororesin particle and the filler to form a film.

16. The method for producing the fluororesin sheet according to claim 15, comprising mixing only the fluororesin particle and an inorganic filler to form a film without addition of other components.

17. A copper-clad laminate comprising copper foil and the fluororesin sheet according to claim 13 as essential layers.

18. A circuit board having the copper-clad laminate according to claim 17.
